(19) United States
(12) Patent Application Publication
(10) Pub. No.: US 2014/0178566 A1
(43) Pub. Date: Jun. 26, 2014

(54) PATTERN FORMING APPARATUS AND METHOD, AND METHOD OF MANUFACTURING SUBSTRATE FORMED WITH PATTERN

(71) Applicant: FUJIFILM CORPORATION, Tokyo (JP)

(72) Inventor: Jun KODAMA, Ashigarakami-gun (JP)

(73) Assignee: FUJIFILM CORPORATION, Tokyo (JP)

(21) Appl. No.: 14/191,157

(22) Filed: Feb. 26, 2014

Related U.S. Application Data
(63) Continuation of application No. PCT/JP2012/072276, filed on Aug. 27, 2012.

(30) Foreign Application Priority Data
Aug. 29, 2011 (JP) 2011-186300

(51) Int. Cl. H05K 3/42

(52) U.S. Cl. CPC H05K 3/422
USPC 427/8; 118/712

(57) ABSTRACT

A pattern forming apparatus includes: a laser irradiation device configured to emit and direct a beam of laser light to enter a hole through an opening section thereof formed in a substrate; a light reflection device having a reflective surface configured to reflect the laser light to irradiate an inner surface of the hole with the reflected laser light, the reflective surface being arranged on a bottom of the hole to face toward the opening section; a droplet ejection device configured to eject and deposit droplets of conductive ink into the hole; and a control device configured to control the laser irradiation device to irradiate and modify the inner surface of the hole with the laser light reflected on the reflective surface, and to control the droplet ejection device to eject and deposit the droplets of the conductive ink into the hole of which the inner surface has been modified.

### TECHNICAL FIELD

The present invention relates to a pattern forming apparatus and a pattern forming method for depositing droplets of conductive ink onto inner surfaces of holes so as to form conductors serving as wires, and especially to a pattern forming apparatus, a pattern forming method and a method of manufacturing a substrate formed with patterns, in which only inner surfaces of holes such as via holes, contact holes and through holes are modified to have affinity for conductive ink, and then droplets of the conductive ink are deposited onto the modified inner surfaces of the holes so as to form conductors serving as wires.

### BACKGROUND ART

In recent years, attention has been paid to technology for forming fine patterns, such as electronic circuit wiring or electrical wiring patterns on a substrate, or the like. Moreover, in multi-layer circuit boards, and the like, attention has also been paid to technology for forming conductors which make connections between layers or to external components.

A liquid ejection head (inkjet head) based on an inkjet method can be used for forming the above-described fine patterns. In this case, an inkjet head ejects and deposits droplets of a liquid in which metal particles or resin particles are dispersed, to form a pattern, which is then cured by heat, or the like, to form an electrical wiring pattern.

PTL 1 describes a manufacturing method for a multi-layer circuit board, in which an insulating layer is formed of photocurable resin on an inner layer circuit substrate where an inner layer circuit has been formed, the insulating layer is exposed to light through a photo mask with which parts where via holes are to be formed are masked, the unexposed resin is then removed by a developer to form holes to become the via holes, and metal is applied on the inner surfaces of the holes to electrically connect the inner layer circuit and an outer layer circuit. PTL 1 further describes that all of the holes are irradiated with laser light in the range of 50 μm to 100 μm in order to improve productivity and reduce the resin remaining in the holes. PTL 1 also describes improved efficiency compared to a case where all holes are opened by a laser via method, since the hole opening process by means of laser is restricted to small diameter holes after simultaneous hole opening process by the photo via method.

PTL 2 describes a method of forming wiring, in which, in order to control aging deterioration in the insulating characteristics between holes arranged through an insulating layer, while assuring adhesiveness of wires formed on the inner surfaces of the holes, ozone solution processing is carried out to bring a solution containing ozone into contact with the inner surfaces of the holes formed in the insulating layer, whereupon conductive layers are formed by electroless plating on at least the inner surfaces of the holes so as to form the wires on these inner surfaces. PTL 2 also describes carrying out ozone solution/ultraviolet light irradiation processing in which the inner surfaces are irradiated with ultraviolet light while being in contact with the solution containing ozone, instead of the ozone solution processing.

### CITATION LIST

### Patent Literature

PTL 1: Japanese Patent Application Publication No. 2001-177252
PTL 2: Japanese Patent Application Publication No. 2005-050999

### SUMMARY OF INVENTION

### Technical Problem

The method described in PTL 1 has a problem in that when the conductive ink is dripped toward the holes, the conductive ink does not enter the holes of which the inner surfaces have not undergone the modification.

In the method described in PTL 2, the substrate is immersed in the ozone solution, or the ozone solution is sprayed to the substrate. Thereby, the surface modification is not necessarily applied to only the inner surfaces of the holes. Consequently, there is a problem in that when the conductive ink is dripped toward the holes, the conductive ink is scattered to parts that have undergone the surface modification other than the holes.

### Solution to Problem

The present invention has been contrived in view of these circumstances, an object thereof being to provide a pattern forming apparatus, a pattern forming method and a method of manufacturing a substrate formed with patterns, in which the inner surfaces of holes, such as through holes, are modified and conductors can be formed in the holes.

In order to attain the aforementioned object, the present invention is directed to a pattern forming apparatus, comprising: a data acquisition device configured to acquire laser irradiation data and droplet deposition data in accordance with shape information of a substrate that has been formed with a hole; a laser irradiation device configured to emit and direct a beam of laser light to enter the hole through an opening section thereof; a light reflection device having a reflective surface configured to reflect the laser light entering the hole through the opening section thereof to irradiate an inner surface of the hole with the reflected laser light, the reflective surface being arranged on a bottom of the hole to face toward the opening section thereof; a droplet ejection device configured to eject and deposit droplets of conductive ink into the hole; and a control device configured to control the laser irradiation device in accordance with the laser irradiation data to irradiate and modify the inner surface of the hole with the laser light reflected on the reflective surface, and to control the droplet ejection device in accordance with the droplet deposition data to eject and deposit the droplets of the conductive ink into the hole of which the inner surface has been modified.

According to this aspect of the present invention, the laser light entering the hole through the opening section thereof is reflected on the reflective surface of the light reflection device, and the inner surface of the hole is irradiated with the reflected laser light. Consequently, it is possible to modify only the inner surface of the hole. By then depositing the droplets of the conductive ink into the hole of which the inner surface has been modified, it is possible to form a conductor in the hole.

The hole can have a diameter which is uniform or increases from the opening section to the bottom of the hole.

The hole can pass through the substrate, and the reflective surface of the light reflection device can be arranged on a lower surface of the substrate. Accordingly, it is possible to modify only the inner surface of the hole passing through the substrate.

The reflective surface of the light reflection device can be a surface of an electrode arranged at a position matching the bottom of the hole. Accordingly, it is possible to modify the inner surface of the hole having the bottom at which the electrode is arranged.

The reflective surface of the light reflection device can be metallic.

The reflective surface of the light reflection device can be formed with a light diffusing structure. Accordingly, the incident laser light can be diffusely reflected on the reflective surface, and the inner surface of the hole can be appropriately irradiated with the reflected laser light.

It is possible that the pattern forming apparatus further comprises a deviation determination device configured to determine deviation of the substrate, and the control device is configured to correct the laser irradiation data and the droplet deposition data in accordance with the deviation of the substrate determined by the deviation determination device. According to this aspect of the present invention, even if there is deviation in the substrate, the inner surface of the hole can be modified and the conductor can be formed in the hole.

The deviation determination device can be configured to determine the deviation of the substrate with alignment marks formed on the substrate.

The beam of the laser light can have a diameter smaller than a diameter of the opening section of the hole.

The beam of the laser light can have a diameter smaller than a diameter of each of the droplets of the conductive ink.

The control device can be configured to control the droplet ejection device to perform ejection and deposition of the droplets of the conductive ink into the hole of which the inner surface has been modified, by dividing the ejection and deposition into a plurality of actions. According to this aspect of the present invention, it is possible to prevent air bubbles having entered the hole from obstructing the droplets of the conductive ink and causing cavities.

It is possible that the pattern forming apparatus further comprises a gas supply device configured to supply reactive gas to the hole, and the control device is configured to control the gas supply device to supply the reactive gas to the hole while controlling the laser irradiation device to irradiate the inner surface of the hole with the laser light reflected on the reflective surface. According to this aspect of the present invention, it is possible to promote the modification of the inner surface of the hole.

The reactive gas can include at least one of oxygen, nitrogen, fluorine and hydrogen.

The hole can be one of a via hole, a contact hole and a through hole.

In order to attain the aforementioned object, the present invention is also directed to a pattern forming method, comprising the steps of: acquiring laser irradiation data and droplet deposition data in accordance with shape information of a substrate that has been formed with a hole; arranging a reflective surface of a light reflection device on a bottom of the hole to face toward an opening section of the hole; directing a beam of laser light in accordance with the laser irradiation data to enter the hole through the opening section thereof to irradiate and modify an inner surface of the hole with the laser light reflected on the reflective surface; and depositing droplets of conductive ink in accordance with the droplet deposition data into the hole of which the inner surface has been modified.

It is possible that the pattern forming method further comprises the steps of: determining deviation of the substrate; and correcting the laser irradiation data and the droplet deposition data in accordance with the determined deviation of the substrate.

It is possible that the pattern forming method further comprises the step of supplying reactive gas to the hole simultaneously with the directing of the beam of the laser light to enter the hole.

In order to attain the aforementioned object, the present invention is also directed to a method of manufacturing a substrate formed with patterns, the method comprising the steps of: acquiring laser irradiation data and droplet deposition data in accordance with shape information of a substrate that has been formed with a hole; arranging a reflective surface of a light reflection device on a bottom of the hole to face toward an opening section of the hole; directing a beam of laser light in accordance with the laser irradiation data to enter the hole through the opening section thereof to irradiate and modify an inner surface of the hole with the laser light reflected on the reflective surface; and depositing droplets of conductive ink in accordance with the droplet deposition data into the hole of which the inner surface has been modified.

It is possible that the method further comprises the steps of: determining deviation of the substrate; and correcting the laser irradiation data and the droplet deposition data in accordance with the determined deviation of the substrate.

It is possible that the method further comprises the step of supplying reactive gas to the hole simultaneously with the directing of the beam of the laser light to enter the hole.

### Advantageous Effects of Invention

According to the present invention, since the light reflection surface is arranged at the bottom of the hole and the beam of laser light is caused to enter the hole though the opening section thereof, then the laser light entering the hole is reflected on the light reflection surface, and the inner surface of the hole can be irradiated and modified with the reflected laser light.

### BRIEF DESCRIPTION OF DRAWINGS

FIG. 1 is a schematic drawing showing a pattern forming apparatus according to a first embodiment of the present invention.

FIG. 2A is a schematic drawing showing a substrate which can be used in the first embodiment.

FIG. 2B is a schematic cross-sectional diagram of a substrate which can be used in the first embodiment.

FIG. 2C is a schematic cross-sectional diagram of another substrate which can be used in the first embodiment.

FIG. 3 is a schematic drawing showing a composition of a laser irradiation unit.

FIG. 4 is a schematic drawing showing diffuse reflection of laser light.

FIG. 5 is a schematic perspective diagram showing a pattern forming method.

FIG. 6A is a schematic cross-sectional diagram showing a step of pattern forming process in the first embodiment.

FIG. 6B is a schematic cross-sectional diagram showing a step of pattern forming process in the first embodiment.

FIG. 6C is a schematic cross-sectional diagram showing a step of pattern forming process in the first embodiment.

FIG. 6D is a schematic cross-sectional diagram showing a step of pattern forming process in the first embodiment.

FIG. 7A is a schematic cross-sectional diagram showing a step of pattern forming process in a second embodiment of the present invention.

FIG. 7B is a schematic cross-sectional diagram showing a step of pattern forming process in the second embodiment.

FIG. 7C is a schematic cross-sectional diagram showing a step of pattern forming process in the second embodiment.

FIG. 7D is a schematic cross-sectional diagram showing a step of pattern forming process in the second embodiment.

FIG. 7E is a schematic cross-sectional diagram showing a step of pattern forming process in the second embodiment.

FIG. 8A is a schematic cross-sectional diagram showing a step of pattern forming process in a third embodiment of the present invention.

FIG. 8B is a schematic cross-sectional diagram showing a step of pattern forming process in the third embodiment.

FIG. 8C is a schematic cross-sectional diagram showing a step of pattern forming process in the third embodiment.

FIG. 8D is a schematic cross-sectional diagram showing a step of pattern forming process in the third embodiment.

FIG. 8E is a schematic cross-sectional diagram showing a step of pattern forming process in the third embodiment.

FIG. 9A is a schematic cross-sectional diagram showing a step of pattern forming process in a fourth embodiment of the present invention.

FIG. 9B is a schematic cross-sectional diagram showing a step of pattern forming process in the fourth embodiment.

FIG. 9C is a schematic cross-sectional diagram showing a step of pattern forming process in the fourth embodiment.

FIG. 9D is a schematic cross-sectional diagram showing a step of pattern forming process in the fourth embodiment.

FIG. 10A is a schematic cross-sectional diagram showing a step of pattern forming process in a fifth embodiment of the present invention.

FIG. 10B is a schematic cross-sectional diagram showing a step of pattern forming process in the fifth embodiment.

FIG. 10C is a schematic cross-sectional diagram showing a step of pattern forming process in the fifth embodiment.

FIG. 10D is a schematic cross-sectional diagram showing a step of pattern forming process in the fifth embodiment.

### DESCRIPTION OF EMBODIMENTS

### First Embodiment

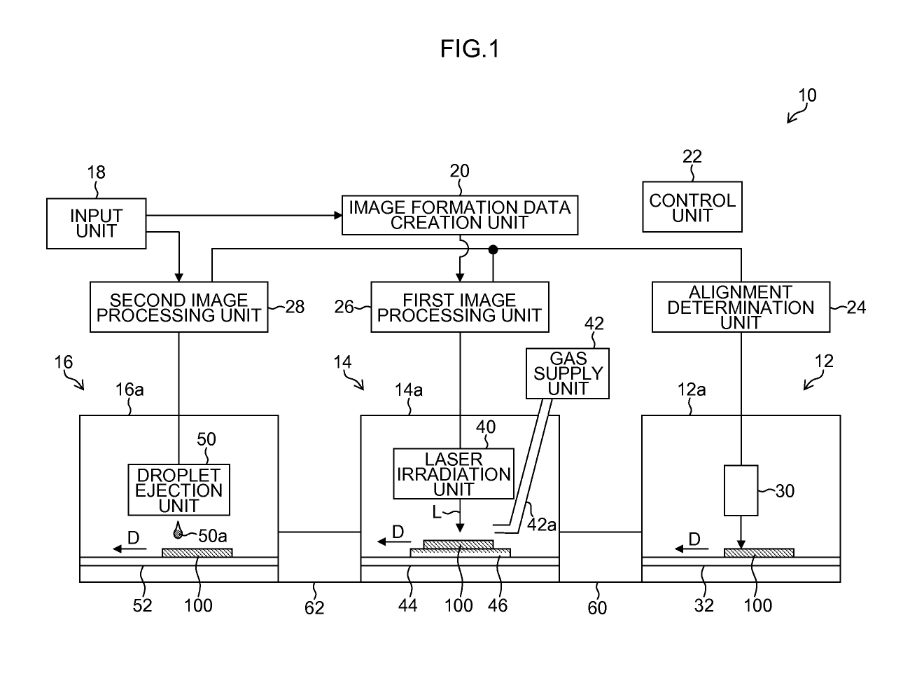

FIG. 1 is a schematic drawing showing a pattern forming apparatus 10 according to a first embodiment of the present invention. The pattern forming apparatus 10 modifies only the inner surfaces of holes, such as via holes, contact holes and through holes, and then forms conductors in the holes. In the present embodiment, although the via holes are described as examples of the holes, the parts of which the inner surfaces can be modified and applied with conductors are not limited to the via holes but include any holes, grooves, or the like, for forming wires in electronic elements constituting an electronic circuit, or contact holes, through holes, or the like, prepared to connect layers in multi-layer circuit boards, thin film transistors (TFT), and the like, and more specifically, in manufacturing of solar batteries, electronic papers, organic electroluminescence (EL) elements, organic EL displays, and the like. Moreover, the side faces of some structures can be modified and applied with conductors, similarly to the inner surfaces of holes and grooves.

As shown in FIG. 1, the pattern forming apparatus 10 includes: a deviation determination unit 12; a modification processing unit 14; a pattern formation unit 16; an input unit 18, through which pattern data such as alignment position information of a substrate 100 and via hole formation position information are inputted; an image formation data creation unit 20; a control unit 22; an alignment determination unit 24; a first image processing unit 26; and a second image processing unit 28. The constituent parts of the pattern forming apparatus 10 are controlled by the control unit 22.

The deviation determination unit 12 is connected to the modification processing unit 14 through a first transfer unit 60. The modification processing unit 14 is connected to the pattern formation unit 16 through a second transfer unit 62.

The pattern forming apparatus 10 shown in FIG. 1 is of a single substrate processing type, which processes the substrates 100 one by one, but is not limited to this. The pattern forming apparatus 10 can be of a roll-to-roll processing type, which processes a long substrate conveyed continuously, for example.

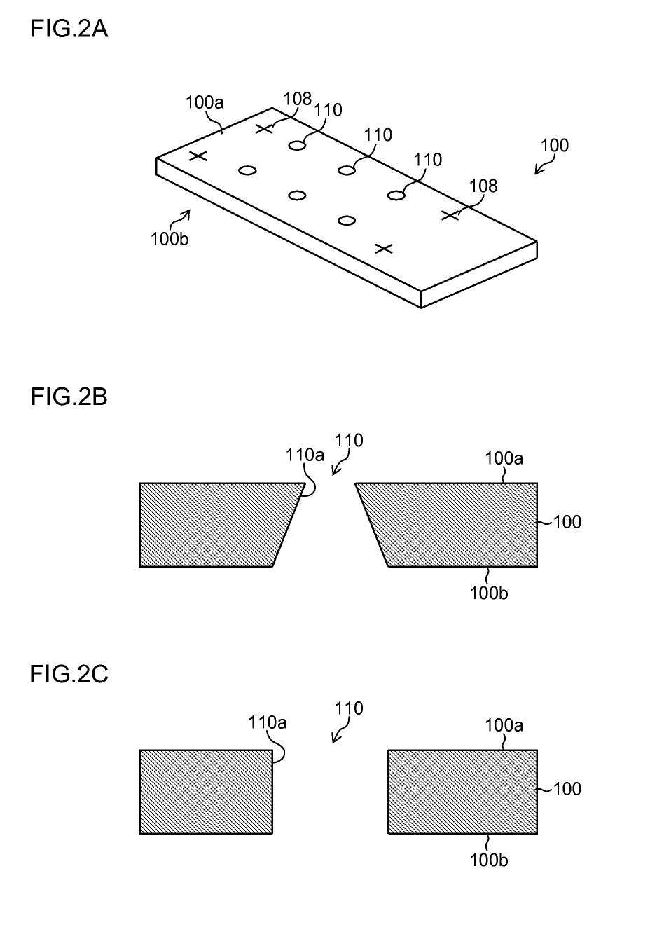

FIGS. 2A to 2C show the substrate 100, which can be used in the pattern forming apparatus 10 according to the present embodiment. As shown in FIG. 2A, the substrate 100 is a thin plate-shaped member, which can be made of acrylic resin, polyimide resin, glass epoxy resin, or the like.

Via holes 110 are formed previously in the substrate 100. The via holes 110 are through holes for making connections between wiring layers formed respectively on an upper surface 100a and a lower surface 100b of the substrate 100 that serves as an insulating layer.

FIG. 2B is a schematic cross-sectional diagram of the substrate 100 at the position where one of the via holes 110 has been formed. As shown in FIG. 2B, the diameter of the via hole 110 increases from an upper opening at the upper surface 100a to a lower opening at the lower surface 100b in FIG. 2B. In other words, the via hole 110 has a trapezoidal cross-sectional shape. It is also possible that the via hole 110 has a uniform diameter from the upper opening at the upper surface 100a to the lower opening at the lower surface 100b, or a rectangular cross-sectional shape, as shown in FIG. 2C.

A plurality of alignment marks 108 for positional alignment are formed on the upper surface 100a of the substrate 100, as shown in FIG. 2A. The alignment marks 108 can be cross-shaped symbols, for instance.

The deviation determination unit 12 shown in FIG. 1 determines a deviation of the substrate 100. The deviation determination unit 12 has a deviation sensor 30, which determines the deviation of the substrate 100 and is arranged in a chamber 12a. The deviation sensor 30 is connected to the alignment determination unit 24. The deviation determination unit 12 has a conveyance mechanism 32, which supports and conveys the substrate 100. The conveyance mechanism 32 is arranged in the chamber 12a, and the substrate 100 is placed on a prescribed table in the determination region of the deviation sensor 30 and is moved in a conveyance direction D, for example, while being held in a prescribed attitude. The conveyance mechanism 32 is not limited to the mechanism that conveys the substrate 100 in a single direction, such as the conveyance direction D, but can be a mechanism that conveys the substrate 100 in two orthogonal directions.

The deviation sensor 30 has an optical system including a light source, such as a laser diode (LD) or a light-emitting diode (LED), and an imaging element, such as a complementary metal oxide semiconductor (CMOS) image sensor or a charge coupled device (CCD) image sensor. The deviation sensor 30 captures images of the alignment marks 108, which are arranged in advance on the substrate 100, and obtains image data of the alignment marks 108. The image data is outputted to the alignment determination unit 24.

The alignment determination unit 24 creates information representing deviation of the substrate 100 (including deviation in the image formation thereof) by calculating sizes and orientations of the alignment marks 108, and distances between the alignment marks 108, for example, on the basis of the image data of the alignment marks 108 obtained through the deviation sensor 30, and comparing these values with design value data for the alignment marks 108. The deviation information of the substrate 100 (including the imaging deviation information) is outputted to both of the first image processing unit 26 and the second image processing unit 28. As described hereinafter, the first image processing unit 26 and the second image processing unit 28 correct laser irradiation data and droplet deposition data, respectively, in accordance with the deviation information of the substrate 100 (including the imaging deviation information).

In the present embodiment, the deviation of the substrate 100 includes the imaging deviation, in addition to the deviation of the substrate 100 itself The deviation of the substrate 100 includes deviations of the substrate 100 from a prescribed position in directions parallel or perpendicular to the table on which the substrate 100 is placed, a rotational deviation of the substrate 100, and a distortion of the substrate 100. The imaging deviation includes a deviation in the imaging position, and imaging distortions, such as enlargement or reduction of the imaged shape and deformation of the imaged shape into a trapezoidal shape, or the like.

There are no particular restrictions on the mode of capturing the images of the alignment marks 108 by the deviation sensor 30; for example, there is a mode where the images of the alignment marks 108 on the substrate 100 that is fixed in position, are captured by moving the deviation sensor 30 two-dimensionally, or a mode where the images of the alignment marks 108 on the substrate 100 that is moved with the conveyance mechanism 32 are captured by the deviation sensor 30 that is stationary, or the like.

The modification processing unit 14, which is arranged after the deviation determination unit 12, performs a modification process on inner surfaces 110a of the via holes 110 formed in the substrate 100. As shown in FIG. 1, the modification processing unit 14 includes a chamber 14a, a laser irradiation unit 40, a gas supply unit 42, a conveyance mechanism 44, and the like. The chamber 14a contains the laser irradiation unit 40, a pipe 42a connected to the gas supply unit 42, the conveyance mechanism 44, and a light reflection plate 46. The laser irradiation unit 40 is connected to the first image processing unit 26.

The conveyance mechanism 44 is arranged inside the chamber 14a, and the substrate 100 is placed on a prescribed table in the irradiation region of the laser irradiation unit 40 and is moved in the conveyance direction D, for example, while being held in a prescribed attitude.

The light reflection plate 46 serving as a light reflection device is arranged on an upper surface of the conveyance mechanism 44. The light reflection plate 46 is a thin plate having a reflective surface configured to diffusely reflect incident laser light. The light reflection plate 46 can be made of aluminum (Al), silver (Ag), copper (Cu), gold (Au), stainless steel (SUS), and the like, or a thin resin plate of which the surface is coated with the metal by metal vapor deposition or metal plating. It is possible to form a diffusing structure capable of diffusely reflecting the incident laser light, by forming fine unevenness, arranging metal particles to make unevenness, applying glass powder, or the like, onto the metallic reflective surface of the light reflection plate 46. Moreover, it is also possible to adopt a mode where a member capable of transmitting the laser light is arranged over the reflective surface of the light reflection plate 46.

It is also possible to adopt a mode in which, rather than arranging the light reflection plate 46 on the upper surface of the conveyance mechanism 44, a diffusing structure is formed of the metal directly on the upper surface of the conveyance mechanism 44 in such a manner that the conveyance mechanism 44 has the reflective surface configured to diffusely reflect the incident laser light. When the conveyance mechanism 44 is thus composed, it is possible to arrange the substrate 100 directly on the upper surface of the conveyance mechanism 44 that also serves as the light reflection device, and the light reflection plate 46 is not necessary.

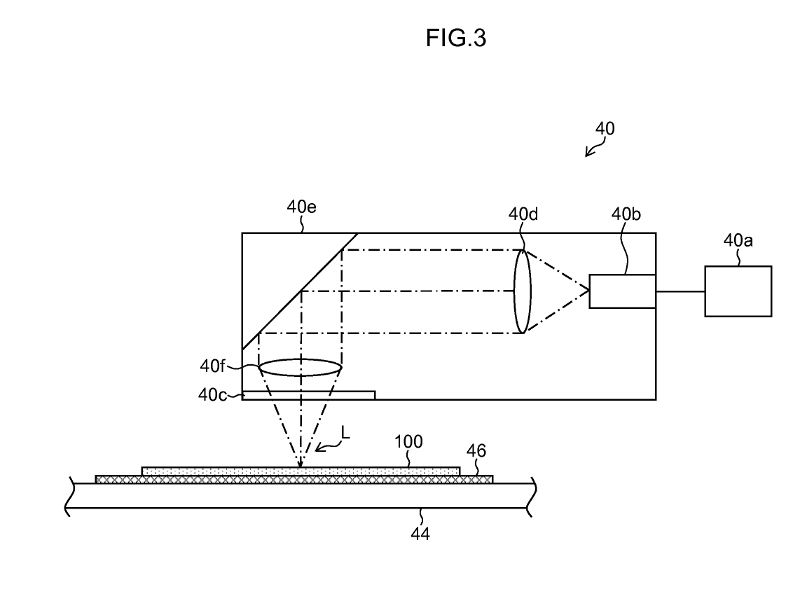

In FIGS. 1 and 3, the substrate 100 is arranged on the upper surface of the light reflection plate 46. Then, the upper surface or the reflective surface of the light reflection plate 46 faces the openings of the via holes 110. The conveyance mechanism 44 conveys the substrate 100 as well as the light reflection plate 46.

The laser irradiation unit 40 emits and directs a beam of laser light L to the via holes 110. As shown in FIG. 3, the laser irradiation unit 40 includes a drive unit 40a, a laser oscillator 40b, a shutter mechanism 40c, a collimating lens 40d, a lens system 40e for adjusting the emitted beam of laser light L, and a front end optical system (mirror, lens, or the like) 40f for directing the beam of laser light L to irradiate a spot having a required diameter on the surface of an irradiation object.

The laser irradiation unit 40 which is composed as described above irradiates the via holes 110 of the substrate 100 with the laser light L. In this case, the beam diameter of laser light L emitted from the laser irradiation unit 40 (i.e., the beam spot diameter) is adjusted so as to be smaller than the diameter of the opening of the via hole 110. Consequently, the upper surface 100a of the substrate 100 is not irradiated with the laser light L, while only the inner sides of the via holes 110 are irradiated with the laser light L.

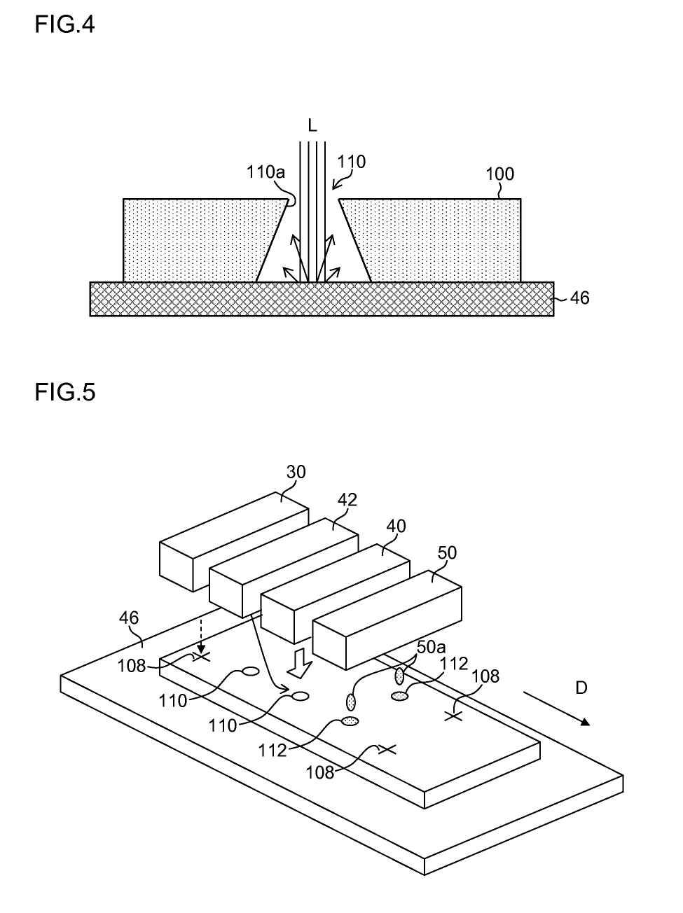

As shown in FIG. 4, the laser light L that enters through the opening of the via hole 110 in the upper surface of the substrate 100 is diffusely reflected on the reflective surface of the light reflection plate 46, which is arranged on the lower surface of the substrate 100. The inner surface 110a of the via hole 110 is irradiated with the reflected laser light L and thereby modified. The laser irradiation unit 40 can direct the beam of laser light L to have a prescribed incident angle with respect to the reflective surface of the light reflection plate 46, in such a manner that the inner surface 110a of the via hole 110 is appropriately irradiated with the reflected laser light L.

In the modification processing unit 14, the laser irradiation unit 40 scans the substrate 100 with the beam of laser light L in a direction perpendicular to the conveyance direction D of the substrate 100, for example, and thereby carries out the modification processing in the region of the substrate 100 where the modification processing can be performed in one scanning action in this direction. When one modification processing action in the scanning direction has been completed, the substrate 100 is moved by a prescribed amount, and the modification processing is then carried out in the next region. By repeating these actions, the modification processing is performed in a serial method on all of the via holes 110 formed in the substrate 100.

In order to scan the substrate 100 with the beam of laser light L in the modification processing, the laser irradiation unit 40 can be moved in the scanning direction, or can be provided with a scanning optical unit (not shown) to perform the scanning action of the beam of laser light L without moving the laser irradiation unit 40. Moreover, it is also possible to adopt a composition in which the laser irradiation unit 40 can emit a plurality of beams of laser light L so that the beams are arranged in the width direction perpendicular to the conveyance direction D of the substrate 100.

The laser light emitted from the laser irradiation unit 40 can be an ultraviolet light or a visible light, such as a light having a wavelength of 300 nm, 365 nm, 405 nm, or the like, or can be an infrared light. The laser irradiation unit 40 has an output power to cause the reflected laser light to modify the inner surface 110a of the via hole 110, and emits the beam of laser light of 10 mJ/cm² to several hundreds mJ/cm², for example, having the beam spot diameter that is smaller than the diameters of ink droplets and the via holes 110 and is in a range of 1 μm to 2 μm, for example. Here, the diameter of the via hole 110 means the minimum value of the diameter if there is variation in the diameter of the via hole 110.

In the laser irradiation unit 40, provided that the unit can emit the laser light as described above, it is possible to use various types of units, such as a semiconductor laser unit, a solid laser unit, a liquid laser unit, a gas laser unit, or the like.

The gas supply unit 42 supplies a reactive gas for modification processing, to the via holes 110 formed in the substrate 100 while being irradiated with the laser light L for the same modification processing. The concentration (fill amount) of the reactive gas in the via holes 110 formed in the substrate 100, and the like, is adjusted by the gas supply unit 42.

The gas supply unit 42 is connected to the pipe 42a, through which the reactive gas is supplied to the via holes 110 of the substrate 100. Moreover, the gas supply unit 42 is connected to the control unit 22, which controls the supply amount, supply timing, and the like, of the reactive gas supplied from the gas supply unit 42.

For the reactive gas, it is possible to use air, oxygen, nitrogen, a fluorine gas such as CF₂ or CF₄, hydrogen, or a mixture of these.

If the gas supply unit 42 is configured to be able to selectively supply a plurality of reactive gases into the chamber 14a, then expulsion of the reactive gas from the chamber 14a and supply of another reactive gas to the via holes 110 of the substrate 100 are carried out appropriately, in accordance with requirements.

Here, the modification processing for ensuring that droplets 50a of the conductive ink do not adhere to parts other than the inner surfaces 110a of the via holes 110 can be a treatment to strengthen the affinity of the inner surfaces 110a for the liquid, or a treatment to strengthen the repellency of the inner surfaces 110a to the liquid, depending on the characteristics of the conductive ink, for example.

In the present embodiment, it is possible to switch the treatments to strengthen the affinity for the liquid and to strengthen the repellency to the liquid, by switching the reactive gases used for the modification processing of the inner surface. For example, when using an aqueous ink, if the inner surface 110a of the via hole 110 is irradiated with the (reflected) laser light L while being supplied with a reactive gas including oxygen or a reactive gas including nitrogen from the gas supply unit 42, then the inner surface 110a of the via hole 110 having been irradiated with the laser light L has a stronger affinity for the liquid than the region having not been irradiated with the laser light L. On the other hand, if the inner surface 110a of the via hole 110 is irradiated with the (reflected) laser light L while being supplied with the fluorine gas from the gas supply unit 42, then the inner surface 110a of the via hole 110 having been irradiated with the laser light L has a stronger repellency to the liquid than the region having not been irradiated with the laser light L.

Here, the state where the inner surface 110a has the stronger affinity for the liquid is a state where the contact angle of the droplet of the liquid with respect to the inner surface 110a is relatively small, and the state where the inner surface 110a has the stronger repellency to the liquid is a state where the contact angle of the droplet of the liquid with respect to the inner surface 110a is relatively large.

A concrete example of the state where the surface has the strong affinity for the liquid is a state where the contact angle of the droplet of the liquid with respect to the surface is not larger than 45°. A concrete example of the state where the surface has the strong repellency to the liquid is a state where the contact angle of the droplet of the liquid with respect to the surface is not smaller than 80°.

In the modification processing unit 14, only the inner surfaces 110a of the via holes 110 are irradiated with the laser light L emitted from the laser irradiation unit 40, and no other region apart from these is irradiated with the laser light L. Due to the irradiation with the laser light L and the presence of the reactive gas, the inner surfaces 110a of the via holes 110 are modified to have the stronger affinity for the liquid or the stronger repellency to the liquid, for example, as described above.

The pattern formation unit 16 deposits droplets of the conductive ink in the via holes 110 of the substrate 100 after the modification processing. In the pattern formation unit 16, a droplet ejection unit 50 and a conveyance mechanism 52 are arranged in a chamber 16a.

The droplet ejection unit 50 has an inkjet head (not shown) capable of ejecting droplets 50a of the conductive ink, and a driver (not shown) to drive the inkjet head to eject the ink droplets 50a. The driver of the droplet ejection unit 50 is connected to the second image processing unit 28.

There are no particular restrictions on the composition of the inkjet head, provided that the inkjet head is capable of ejecting droplets of the conductive ink, and the inkjet head can be a piezoelectric type, a thermal type, or the like, as appropriate. It is possible to use a serial type or full line type of inkjet head. The size of the ink droplets 50a ejected from the droplet ejection unit 50 is in a range of 10 μm to 100 μm, for example.

As the conductive ink, it is possible to use a wiring ink, such as a metallic liquid in which particles of a metal such as silver (Ag), gold (Au), copper (Cu), or the like, or alloy of these, are dispersed in a prescribed dispersion medium, or a precursor solution containing the above-described metal, provided that the ink has properties (viscosity, etc.) which enable ejection of droplets thereof by the inkjet head, for example. It is possible to form the via of a size of 10 μm to several hundreds μm by means of the conductive ink.

The conveyance mechanism 52 is arranged inside the chamber 16a, and the substrate 100 is placed on a prescribed table in the deposition region of the ink droplets 50a ejected from the droplet ejection unit 50 and is moved in the conveyance direction D, for example, while being held in a prescribed attitude. Depending on the mode of the droplet ejection unit 50, the conveyance mechanism 52 is configured to be able to move the substrate 100 also in the direction perpendicular to the conveyance direction D with respect to the droplet ejection unit 50.

In the pattern formation unit 16, the ink droplets 50a ejected from the droplet ejection unit 50 are deposited onto the inner surfaces 110a of the via holes 110 which have undergone the modification processing. The inner surfaces 110a of the via holes 110 are then buried by the ink droplets 50a.

In a case where the via holes 110 are deep, air bubbles having entered the via holes 110 may obstruct the ink droplets 50a and cause cavities. Hence, it is desirable that the deposition of the ink droplets 50a ejected from the droplet ejection unit 50 into the via holes 110 is divided into a plurality of actions, rather than continuously depositing the ink droplets 50a. For example, ink droplets 50a of a total volume that fills a half of a via hole 110 are ejected and deposited first, and after a prescribed time has elapsed, ink droplets 50a of a total volume of the remaining half are ejected and deposited.

After the conductive ink droplets 50a have been deposited on the inner surfaces 110a of the via holes 110 by the droplet ejection unit 50, the substrate 100 is outputted through a substrate output unit (not shown).

The deposited conductive ink can be irradiated with light (for example, ultraviolet light) or applied with heat in accordance with the characteristics of the conductive ink, so as to be cured to form a via, which serves as a wire. In this case, in order to cure the ink droplets 50a having been deposited on the inner surfaces 110a of the via holes 110, a light irradiation device or a heating device can be arranged directly below the droplet ejection unit 50 or on the downstream side of the droplet ejection unit 50 in the conveyance direction D.

The input unit 18 has an input device (not shown) through which an operator (user) can enter various data, and a display device (not shown). The input device can adopt various modes, such as a keyboard, a mouse, a touch panel, buttons, and the like.

The operator can enter, through the input unit 18 to the control unit 22, various processing conditions for the deviation determination unit 12, the modification processing unit 14 and the pattern formation unit 16, as well as shape information of the substrate 100, position information of the alignment marks 108, shape information such as the size of the alignment marks 108, and the like, and also pattern data such as size, shape and arrangement information of the via holes 110.

The operator can identify, through the display device in the input unit 18, the state of the pattern forming process and the state of the via forming process, such as the states of the deviation determination unit 12, the modification processing unit 14 and the pattern formation unit 16. The display device in the input unit 18 also serves as a device for displaying a warning, such as an error message, and a reporting device which reports an abnormality.

The image formation data creation unit 20 receives the pattern data, such as the size, shape and arrangement information of the via holes, which is inputted through the input unit 18, and converts the pattern data into a data format that can be used in the laser irradiation unit 40 to direct the beam of laser light L to enter the via holes 110 through the openings thereof, so as to create the laser irradiation data usable by the laser irradiation unit 40. In the image formation data creation unit 20, pattern data (e.g., computer-aided design (CAD) data) such as the formation position information of the via holes 110 described in a vector format is converted into raster data, for example. When the pattern data, such as the via hole formation position information, or the like, is inputted through the input unit 18 in the data format that is usable in the laser irradiation unit 40, the data conversion is not particularly necessary. In this case, it is possible to send the inputted pattern data directly to the first image processing unit 26 without data conversion in the image formation data creation unit 20, or without going through the image formation data creation unit 20.

Moreover, the image formation data creation unit 20 can also create the laser irradiation data in accordance with the substrate shape information.

The first image processing unit 26 is connected to the image formation data creation unit 20 and the alignment determination unit 24. When the deviation determination unit 12 has determined deviation in the substrate 100, the first image processing unit 26 corrects the laser irradiation data to create corrected laser irradiation data in order to change the irradiation positions with the beam of laser light L in accordance with the deviation information of the substrate 100 thus determined. The first image processing unit 26 outputs the corrected laser irradiation data to the drive unit 40a in the laser irradiation unit 40. The laser irradiation unit 40 directs the beam of laser light L to the via holes 110 in accordance with the corrected laser irradiation data inputted to the drive unit 40a.

When no deviation is determined in the substrate 100 by the deviation determination unit 12, the first image processing unit 26 does not correct the laser irradiation data. Thereby, the laser irradiation data inputted to the first image processing unit 26 is outputted without being altered, to the drive unit 40a of the laser irradiation unit 40. The laser irradiation unit 40 directs the beam of laser light L to the via holes 110 in accordance with the laser irradiation data inputted to the drive unit 40a.

The second image processing unit 28 is connected to the input unit 18 and the alignment determination unit 24. The pattern data such as the size, shape, arrangement information of the via holes, which is inputted through the input unit 18, can be used as droplet deposition data in the droplet ejection unit 50, without data conversion.

When the deviation determination unit 12 has determined deviation in the substrate 100, the second image processing unit 28 corrects the droplet deposition data to create corrected droplet deposition data in order to change the deposition positions of the ink droplets to 50a in accordance with the deviation information of the substrate 100 thus determined. The second image processing unit 28 outputs the corrected droplet deposition data to the driver (not shown) of the droplet ejection unit 50. In the droplet ejection unit 50, the ink droplets 50a are ejected and deposited onto the inner surfaces 110a of the via holes 110 in accordance with the corrected droplet deposition data inputted to the driver of the droplet ejection unit 50.

When no deviation is determined in the substrate 100 by the deviation determination unit 12, the second image processing unit 28 does not correct the droplet deposition data. Thereby, the droplet deposition data inputted to the second image processing unit 28 is outputted without being altered, to the driver of the droplet ejection unit 50. In the droplet ejection unit 50, the ink droplets 50a are ejected and deposited onto the inner surfaces 110a of the via holes 110 in accordance with the droplet deposition data inputted to the driver of the droplet ejection unit 50.

When the position of the substrate 100 is rotated with respect to the prescribed position, for example, the first image processing unit 26 and the second image processing unit 28 calculate the amount of the rotation of the substrate 100 and generate correction data so as to cancel out the rotation, on demand. Thereupon, the first image processing unit 26 and the second image processing unit 28 generate the corrected laser irradiation data and the corrected droplet deposition data, respectively, corresponding to the correction data of the pattern, on demand. Here, the corrected laser irradiation data and the corrected droplet deposition data include the laser irradiation data (the via hole formation position information) and the droplet deposition data which have been subjected to shift processing (correction of deviation in the planar direction), offset processing (correction of deviation in the thickness direction), rotational processing (correction of deviation in the rotational direction), enlargement processing, reduction processing, trapezoidal correction processing (processing for correcting a pattern that has been distorted to a trapezoidal shape, back into a square shape), or the like.

In the pattern forming apparatus 10 according to the present embodiment, the modification processing unit 14 and the pattern formation unit 16 have a common feedback loop, and are configured to perform correction of the irradiation with the laser light L and correction of the deposition of the ink droplets 50a in accordance with the same and common deviation information of the substrate 100, which is obtained from the deviation determination unit 12. Thus, it is possible to raise the accuracy of correction of the irradiation with the laser light L and the accuracy of correction of the deposition of the ink droplets, and what is to more, since the common deviation information of the substrate is used, then it is possible to speed up the creation of the correction data and the costs required in the correction can be reduced.

It is also possible to prepare a single image processing unit that serves as both the first image processing unit 26 and the second image processing unit 28.

Next, the pattern forming method according to the present embodiment is described.

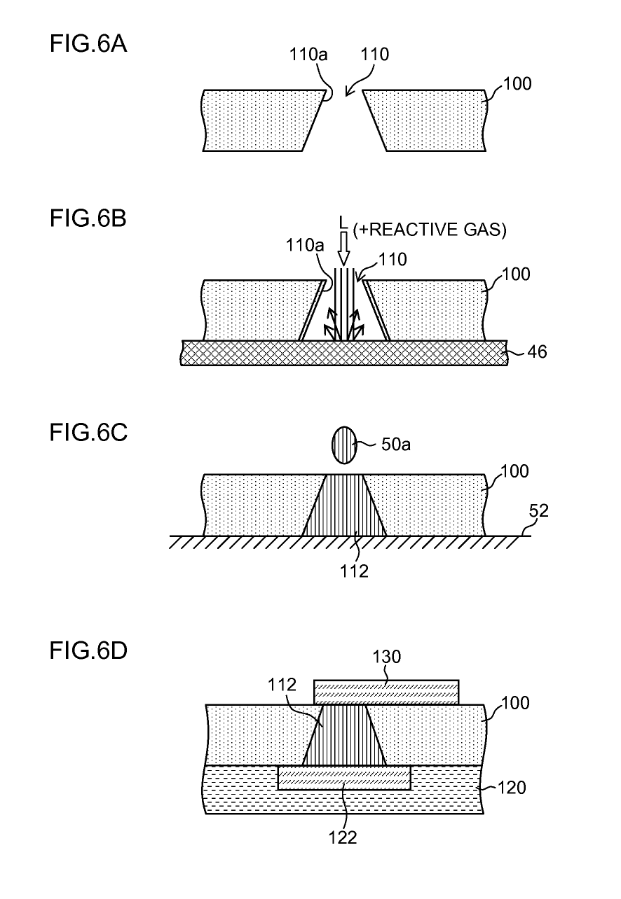

FIG. 5 is a schematic perspective diagram showing a pattern forming method by the pattern forming apparatus 10 in the present embodiment. FIGS. 6A to 6D are schematic cross-sectional diagrams showing steps of one example of pattern forming process by the pattern forming apparatus 10 in the present embodiment.

Firstly, as shown in FIG. 5, images of the alignment marks 108 on the substrate 100, in which the via holes 110 have been previously formed, are captured by the deviation sensor 30, and the alignment determination unit 24 calculates whether or not there is deviation of the substrate 100. The composition of the substrate 100 is the composition shown in FIGS. 2A, 2B and 6A, for example.

When no deviation of the substrate 100 has been determined by the alignment determination unit 24, the first image processing unit 26 sends the laser irradiation data without correction to the laser irradiation unit 40. The laser irradiation unit 40 directs the beam of laser light L to enter the via holes 110 through the opening sections thereof in accordance with the inputted laser irradiation data.

On the other hand, when deviation of the substrate 100 has been determined by the alignment determination unit 24, the first image processing unit 26 creates corrected laser irradiation data by correcting the laser irradiation data in accordance with the determined deviation. The first image processing unit 26 then sends the corrected laser irradiation data thus created to the laser irradiation unit 40, which directs the beam of laser light L to enter the via holes 110 through the opening sections thereof in accordance with the corrected laser irradiation data.

Here, as shown in FIG. 6B, the substrate 100 is placed on the light reflection plate 46. Then, the laser light L entering the via holes 110 through the opening sections thereof is diffusely reflected on the upper surface of the light reflection plate 46, and the inner surfaces 110a of the via holes 110 are irradiated with the reflected laser light. As described above, it is possible that the laser irradiation unit 40 directs the beam of laser light L to have a prescribed incident angle with respect to the upper surface of the light reflection plate 46, in such a manner that the inner surfaces 110a of the via holes 110 are appropriately irradiated with the reflected laser light.

While the laser light L is directed to the via holes 110, if the affinity of the inner surfaces 110a for the liquid is to be strengthened, for example, then a reactive gas including oxygen or nitrogen is supplied from the gas supply unit 42 through the pipe 42a in such a manner that the supplied reactive gas reaches a prescribed concentration at the inner surfaces 110a of the via holes 110. On the other hand, if the repellency of the inner surfaces 110a to the liquid is to be strengthened, then a fluorine gas is supplied from the gas supply unit 42 through the pipe 42a in such a manner that the supplied fluorine gas reaches a prescribed concentration at the inner surfaces 110a of the via holes 110.

By thus directing the beam of laser light L to enter the via holes 110 through the opening sections thereof in accordance with the deviation of the substrate 100 and the formation positions, and the like, of the via holes 110 formed in the substrate 100, it is possible to carry out the modification processing by appropriately irradiating only the inner surfaces 110a with the laser light L.

Next, when no deviation of the substrate 100 has been determined by the alignment determination unit 24, the second image processing unit 28 sends the droplet deposition data without correction to the droplet ejection unit 50. The droplet ejection unit 50 directs the droplets 50a of the conductive ink to enter the via holes 110 as shown in FIG. 6C, in accordance with the inputted droplet deposition data.

On the other hand, when deviation of the substrate 100 has been determined by the alignment determination unit 24, the second image processing unit 28 creates corrected droplet deposition data by correcting the droplet deposition data in accordance with the determined deviation. The second image processing unit 28 sends the corrected droplet deposition data thus created to the droplet ejection unit 50, which directs the droplets 50a of the conductive ink to enter the via holes 110 as shown in FIG. 6C, in accordance with the corrected droplet deposition data.

Thus, the ink droplets 50a are appropriately deposited in the via holes 110 in accordance with the deviation of the substrate 100 and the formation positions, and the like, of the via holes 110 formed in the substrate 100.

The ink droplets 50a having been deposited in the via holes 110 never fall out from the via holes 110, because the substrate 100 is placed on the table of the conveyance mechanism 52 of the pattern formation unit 16 (shown in FIG. 1).

Then, the droplets 50a of the conductive ink having been deposited in the via holes 110 are cured by being either irradiated with light (e.g., ultraviolet light) or applied with heat, depending on requirements, such as the characteristics of the conductive ink, so as to form the vias 112 serving as wires in the via holes 110.

In the case where the vias 112 are formed by ejecting and depositing the ink droplets 50a inside the via holes 110, as in the present embodiment, if the via holes 110 are deep, then air bubbles having entered the via holes 110 may prevent the ink droplets 50a from entering the via holes 110. Therefore, desirably, rather than ejecting and depositing the ink droplets 50a continuously into the via holes 110, the ejection and deposition of the ink droplets 50a is divided into a plurality of actions.

Finally, as shown in FIG. 6D, another substrate 120 having electrodes 122 formed on the upper surface thereof is bonded to the lower surface of the substrate 100, and electrodes 130 are formed at positions matching the vias 112 on the upper surface of the substrate 100.

For the substrate 120, it is possible to use a glass base material, a silicon wafer (silicon base material), a resin film base material, a glass epoxy base material, or the like. The electrodes 122 have been formed at the positions matching the vias 112. There are no particular restrictions on the method of forming the electrodes 130. For example, it is possible to form the electrodes 130 by a photolithography method.

Thus, the vias 112 become the wires connecting the electrodes 122 with the electrodes 130, respectively.

### Second Embodiment

In the first embodiment, the substrate 120 is bonded to the lower surface of the substrate 100 after the vias 112 have been formed inside the via holes 110. It is also possible that, after the inner surfaces 110a of the via holes 110 are modified, the substrate 120 is bonded to the lower surface of the substrate 100 first, and then the vias 112 are formed inside the via holes 110 subsequently.

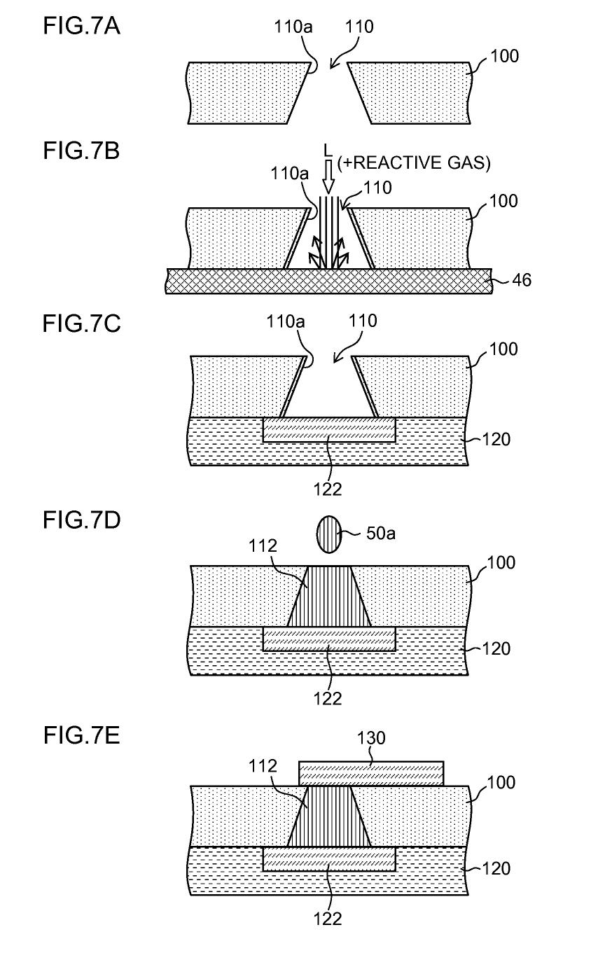

FIGS. 7A to 7E are schematic cross-sectional diagrams showing steps of one example of pattern forming process by the pattern forming apparatus 10 in the second embodiment. Since FIGS. 7A and 7B are similar to FIGS. 6A and 6B, description thereof is omitted here.

After the modification of the inner surfaces 110a of the via holes 110 has been completed as shown in FIG. 7B, the substrate 120 having the electrodes 122 formed on the upper surface thereof is bonded to the lower surface of the substrate 100, as shown in FIG. 7C. The electrodes 122 have been formed at the positions matching the vias 112.

Next, when no deviation of the substrate 100 has been determined by the alignment determination unit 24, the second image processing unit 28 sends the droplet deposition data without correction to the droplet ejection unit 50. On the other hand, when deviation of the substrate 100 has been determined by the alignment determination unit 24, the second image processing unit 28 creates corrected droplet deposition data by correcting the droplet deposition data in accordance with the determined deviation, and sends the corrected droplet deposition data thus created to the droplet ejection unit 50.

The droplet ejection unit 50 directs the droplets 50a of the conductive ink to enter the via holes 110 as shown in FIG. 7D, in accordance with the inputted droplet deposition data or the inputted corrected droplet deposition data. Then, the droplets 50a of the conductive ink having been deposited in the via holes 110 are cured, and the vias 112 serving as wires are formed in the via holes 110, as shown in FIG. 7D.

Finally, as shown in FIG. 7E, the electrodes 130 are formed at the positions matching the vias 112 on the upper surface of the substrate 100.

Thus, it is also possible to form the vias 112 inside the via holes 110 after bonding the substrate 120 on the lower surface of the substrate 100.

### Third Embodiment

In the third embodiment, the substrate 120 is bonded to the lower surface of the substrate 100 first, whereupon the modification of the inner surfaces 110a of the via holes 110 is carried out, and then the vias 112 are formed in the via holes 110.

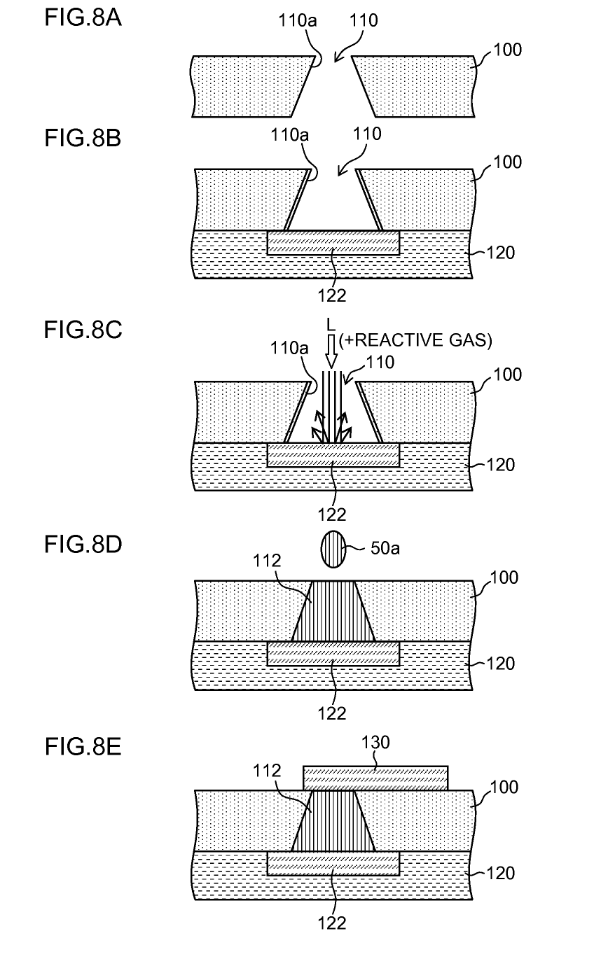

FIGS. 8A to 8E are schematic cross-sectional diagrams showing steps of one example of pattern forming process by the pattern forming apparatus 10 in the third embodiment. Since FIG. 8A is similar to FIGS. 6A and 7A, description thereof is omitted here.

As shown in FIG. 8B, the substrate 120 having been formed with the electrodes 122 is bonded to the lower surface of the substrate 100. The electrodes 122 are arranged at the positions matching the via holes 110, and face toward the opening sections of the via holes 110. The electrodes 122 are made of aluminum (Al), silver (Ag), copper (Cu), gold (Au), molybdenum (Mo), tungsten (W), or the like, or alloy of these, and fine unevenness is formed on the upper surfaces thereof.

Next, when no deviation of the substrate 100 has been determined by the alignment determination unit 24, the first image processing unit 26 sends the laser irradiation data without correction to the laser irradiation unit 40. On the other hand, when deviation of the substrate 100 has been determined by the alignment determination unit 24, the first image processing unit 26 creates corrected laser irradiation data by correcting the laser irradiation data in accordance with the determined deviation, and sends the corrected laser irradiation data thus created to the laser irradiation unit 40.

The laser irradiation unit 40 directs the beam of laser light L to enter the via holes 110 through the opening sections thereof as shown in FIG. 8C, in accordance with the inputted laser irradiation data or the inputted corrected laser irradiation data, while the gas supply unit 42 supplies the prescribed reactive gas through the pipe 42a so as to reach the prescribed concentration.

Here, the fine unevenness is formed on the upper surfaces of the electrodes 122. Hence, the laser light L entering the via holes 110 through the opening sections thereof is diffusely reflected on the upper surfaces of the electrodes 122, and the inner surfaces 110a of the via holes 110 are irradiated with the reflected laser light. Thereby, the inner surfaces 110a are modified. It is possible that the laser irradiation unit 40 directs the beam of laser light L to have a prescribed incident angle with respect to the upper surface of the electrode 122, in such a manner that the inner surface 110a of the via hole 110 is appropriately irradiated with the reflected laser light.

Thereupon, the droplet ejection unit 50 ejects and deposits the droplets 50a of the conductive ink into the via holes 110 as shown in FIG. 8D. Since FIG. 8E is similar to FIG. 7E, description thereof is omitted here.

Thus, by processing the upper surfaces of the electrodes 122, which are arranged at the positions matching the via holes 110, so as to be able to diffusely reflect the laser light L, it is possible to carry out the modification processing of the inner surfaces 110a of the via holes 110 and to form the vias 112, after bonding the substrate 120 on the lower surface of the substrate 100.

In the present embodiment, the light reflection plate 46 of the modification processing unit 14 is not necessary.

### Fourth Embodiment

In the first to third embodiments, the inner surfaces of the via holes are modified. In the fourth embodiment, the inner surfaces of through holes are modified.

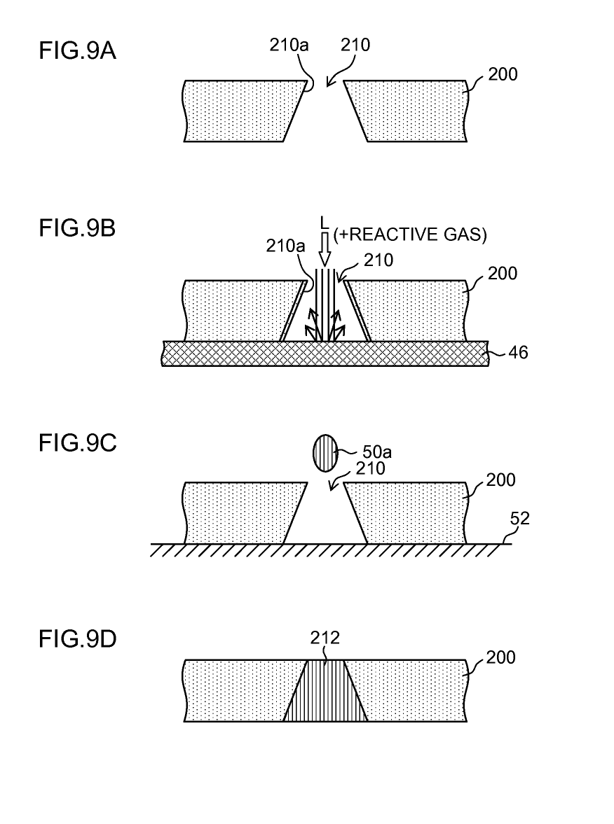

As shown in FIG. 9A, a through hole 210 formed in a substrate 200 has a diameter that increases from an upper opening at the upper surface of the substrate 200 to a lower opening at the lower surface of the substrate 200. In other words, the through hole 210 has a trapezoidal cross-sectional shape. It is also possible that the through hole 210 has a uniform diameter from the upper opening to the lower opening.

The substrate 200 has a similar composition to the substrate 100 shown in FIGS. 2A to 2C, and a plurality of alignment marks (not shown) are formed on the upper surface of the substrate 200 in addition to the through holes 210. The alignment determination unit 24 determines deviation of the substrate 200 by capturing an image of the alignment marks by the deviation sensor 30.

When no deviation of the substrate 200 has been determined by the alignment determination unit 24, the first image processing unit 26 sends the laser irradiation data without correction to the laser irradiation unit 40. On the other hand, when deviation of the substrate 200 has been determined by the alignment determination unit 24, the first image processing unit 26 creates corrected laser irradiation data by correcting the laser irradiation data in accordance with the determined deviation, and sends the corrected laser irradiation data thus created to the laser irradiation unit 40. The laser irradiation unit 40 directs the beam of laser light L to enter the via holes 210 through the opening sections thereof in accordance with the inputted laser irradiation data or the inputted corrected laser irradiation data.

Here, as shown in FIG. 9B, the substrate 200 is placed on the light reflection plate 46. Then, the laser light L entering the through holes 210 through the opening sections thereof is diffusely reflected on the upper surface of the light reflection plate 46, and the inner surfaces 210a of the through holes 210 are irradiated with the reflected laser light.

While the laser light L is directed to the through holes 210, a prescribed gas is supplied from the gas supply unit 42 through the pipe 42a so as to reach a prescribed concentration.

Thus, it is possible to carry out the modification processing by irradiating only the inner surfaces 210a of the through holes 210 with the laser light L.

Next, when no deviation of the substrate 200 has been determined by the alignment determination unit 24, the second image processing unit 28 sends the droplet deposition data to without correction to the droplet ejection unit 50. On the other hand, when deviation of the substrate 200 has been determined by the alignment determination unit 24, the second image processing unit 28 creates corrected droplet deposition data by correcting the droplet deposition data in accordance with the determined deviation, and sends the corrected droplet deposition data thus created to the droplet ejection unit 50.

The droplet ejection unit 50 directs the droplets 50a of the conductive ink to enter the through holes 210 as shown in FIG. 9C, in accordance with the inputted droplet deposition data or the inputted corrected droplet deposition data. Then, the droplets 50a of the conductive ink having been deposited in the through holes 210 are cured, and vias 212 serving as wires are formed in the through holes 210, as shown in FIG. 9D.

Thus, it is possible to appropriately form the vias 212 in the through holes 210 in accordance with the deviation of the substrate 200 and the formation positions, and the like, of the through holes 210 formed in the substrate 200.

### Fifth Embodiment

The pattern forming apparatus 10 can form vias serving as wires in contact holes having been formed in a substrate.

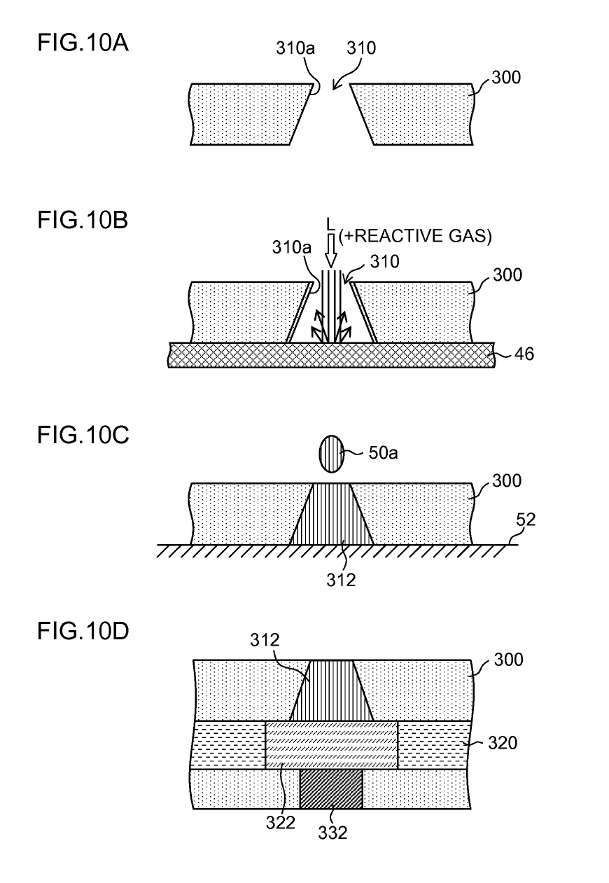

As shown in FIG. 10A, the contact hole 310 formed in the substrate 300 has a diameter that increases from an upper opening at the upper surface of the substrate 300 to a lower opening at the lower surface of the substrate 300. In other words, the contact hole 310 has a trapezoidal cross-sectional shape. It is also possible that the contact hole 310 has a uniform diameter from the upper opening to the lower opening.

The substrate 300 has a similar composition to the substrate 100 shown in FIGS. 2A to 2C, and a plurality of alignment marks (not shown) are formed on the upper surface of the substrate 300 in addition to the contact holes 310.

Similarly to the above-described embodiments, the alignment determination unit 24 determines deviation of the substrate 300 at first. Then, the laser irradiation unit 40 directs the laser light L to enter the via holes 310 through the opening sections thereof as shown in FIG. 10B in accordance with the deviation of the substrate 300 thus determined, while a prescribed gas is supplied. Thereafter, the ink droplets 50a are ejected and deposited in the contact holes 310 from the droplet ejection unit 50 as shown in FIG. 10C in accordance with the determined deviation of the substrate 300, and are then cured.

Then, as shown in FIG. 10D, a substrate 320 in which electrodes 322 have been formed is bonded to the lower surface of the substrate 300. The electrodes 322 are formed at the positions matching the vias 312.

Furthermore, a substrate 330 on which electrodes 332 have been formed is bonded to the lower surface of the substrate 320. The electrodes 332 are formed at the positions matching the electrodes 322.

For the substrates 320 and 330, it is possible to use a glass base material, a silicon wafer (silicon base material), a resin film base material, a glass epoxy base material, or the like.

Thus, it is possible to form the vias 312 in the contact holes 310.

In the above-described embodiments of the present invention, the deviation in the irradiation positions with the laser light can be suppressed by determining the deviation of the substrate (including the deviation in the image formation thereof), and it is possible to modify the inner surfaces of the holes only. Consequently, it is possible to prevent scattering of the ink droplets to parts other than the inner surfaces of the holes, and the vias serving as wires can be formed with high accuracy. Moreover, the deviations in the irradiation positions with the laser light and the deposition positions of the ink droplets can be suppressed by determining the deviation of the substrate, and it is possible to adapt to cases where the substrate is flexible and readily deformable, and further, the vias can be formed with high accuracy.

In the above-described embodiments of the present invention, since the surface modification is carried out by means of the laser light, then it is possible to raise the energy in the surface modification and a high extent of surface modification can be achieved. Consequently, it is possible to accelerate the surface modification, and it is also possible to increase the variation in the composition of the material to be modified. Moreover, by altering the reactive gas, it is possible to achieve compatibility with substrates of various compositions and inks of various compositions.

In the above-described embodiments of the present invention, when the surface modification is carried out by means of the laser light, the light reflection plate or the electrode configured to have the upper surface capable of diffusely reflecting the laser light is arranged at the bottom of each hole in the substrate, and the beam of laser light is directed to enter only the holes through the opening sections thereof. Consequently, the laser light entering each hole through the opening section thereof is diffusely reflected on the upper surface of the light reflection plate or the electrode, and the inner surface of the hole is irradiated with the reflected laser light. Thus, the inner surface of the hole having the diameter that increases from the upper opening to the lower opening can be appropriately irradiated with the laser light.

In the above-described embodiments of the present invention, the surface modification is carried out by means of the laser light and the reactive gas, and therefore no cleaning step is necessary. Hence, it is possible to simplify the manufacturing process. Moreover, since the vias are formed directly, then it is possible to simplify the manufacturing process and reduce the manufacturing costs, in comparison with a photolithography method.

In the above-described embodiments of the present invention, since the laser light irradiation positions and the ink droplet deposition positions are corrected by means of one determination result for the deviation of the substrate, then it is possible to increase the accuracy of the corrections of the laser light irradiation positions and the ink droplet deposition positions, and moreover, the time required to create the corrected laser irradiation data and the corrected droplet deposition data can be shortened. Furthermore, since only one determination result needs to be used, then it is possible to reduce the number of deviation sensors, and costs can be reduced.

In the above-described embodiments of the present invention, the substrates in which the holes such as the via holes, the through holes and the contact holes, and the like, are formed are used. These via holes, through holes, contact holes and the like can be formed in accordance with the formation position information about the via holes, through holes and contact holes, and the like, respectively, by commonly known forming methods used in the manufacturing processes for semiconductor elements and multi-layer wiring substrates, and the like.

The pattern forming apparatus, the pattern forming method and the method of manufacturing the substrate formed with patterns in the embodiments of the present invention can be used for wiring in multi-layer circuit boards, thin film transistors (TFT), and the like, and more specifically, in manufacturing of solar batteries, electronic papers, organic electroluminescence (EL) elements, organic EL displays, and the like. In any of these cases, the embodiments of the present invention are appropriate even if the substrate is flexible, since the deviation of the substrate (including the deviation in the image formation thereof) can be corrected.

### INDUSTRIAL APPLICABILITY

The present invention can be applied to a pattern forming apparatus, a pattern forming method and a method of manufacturing a substrate formed with patterns, for forming wiring in multi-layer circuit boards, thin film transistors, and the like.

### REFERENCE SIGNS LIST

10: pattern forming apparatus; 12: deviation determination unit; 14: modification processing unit; 16: pattern formation unit; 18: input unit; 20: image formation data creation unit; 22: control unit; 24: alignment determination unit; 26: first image processing unit; 28: second image processing unit; 30: deviation sensor; 40: laser irradiation unit; 42: gas supply unit; 50: droplet ejection unit; 50a: ink droplet; 100, 200, 300: substrate; 110: via hole; 112, 212, 312: via; 210: through hole; 310: contact hole; L: laser light

1. A pattern forming apparatus, comprising:
a data acquisition device configured to acquire laser irradiation data and droplet deposition data in accordance with shape information of a substrate that has been formed with a hole;
a laser irradiation device configured to emit and direct a beam of laser light to enter the hole through an opening section thereof;
a light reflection device having a reflective surface configured to reflect the laser light entering the hole through the opening section thereof to irradiate an inner surface of the hole with the reflected laser light, the reflective surface being arranged on a bottom of the hole to face toward the opening section thereof;
a droplet ejection device configured to eject and deposit droplets of conductive ink into the hole; and
a control device configured to control the laser irradiation device in accordance with the laser irradiation data to irradiate and modify the inner surface of the hole with the laser light reflected on the reflective surface, and to control the droplet ejection device in accordance with the droplet deposition data to eject and deposit the droplets of the conductive ink into the hole of which the inner surface has been modified.

2. The pattern forming apparatus as defined in claim 1, wherein the hole has a diameter which is uniform or increases from the opening section to the bottom of the hole.

3. The pattern forming apparatus as defined in claim 1, wherein:
the hole passes through the substrate, and
the reflective surface of the light reflection device is arranged on a lower surface of the substrate.

4. The pattern forming apparatus as defined in claim 1, wherein the reflective surface of the light reflection device is a surface of an electrode arranged at a position matching the bottom of the hole.

5. The pattern forming apparatus as defined in claim 1, wherein the reflective surface of the light reflection device is metallic.

6. The pattern forming apparatus as defined in claim 1, wherein the reflective surface of the light reflection device is formed with a light diffusing structure.

7. The pattern forming apparatus as defined in claim 1, further comprising:
a deviation determination device configured to determine deviation of the substrate,
wherein the control device is configured to correct the laser irradiation data and the droplet deposition data in accordance with the deviation of the substrate determined by the deviation determination device.

8. The pattern forming apparatus as defined in claim 7, wherein the deviation determination device is configured to determine the deviation of the substrate with alignment marks formed on the substrate.

9. The pattern forming apparatus as defined in claim 1, wherein the beam of the laser light has a diameter smaller than a diameter of the opening section of the hole.

10. The pattern forming apparatus as defined in claim 1, wherein the beam of the laser light has a diameter smaller than a diameter of each of the droplets of the conductive ink.

11. The pattern forming apparatus as defined in claim 1, wherein the control device is configured to control the droplet ejection device to perform ejection and deposition of the droplets of the conductive ink into the hole of which the inner surface has been modified, by dividing the ejection and deposition into a plurality of actions.

12. The pattern forming apparatus as defined in claim 1, further comprising:
a gas supply device configured to supply reactive gas to the hole,
wherein the control device is configured to control the gas supply device to supply the reactive gas to the hole while controlling the laser irradiation device to irradiate the inner surface of the hole with the laser light reflected on the reflective surface.

13. The pattern forming apparatus as defined in claim 12, wherein the reactive gas includes at least one of oxygen, nitrogen, fluorine and hydrogen.

14. The pattern forming apparatus as defined in claim 1, wherein the hole is one of a via hole, a contact hole and a through hole.

15. A pattern forming method, comprising the steps of:
acquiring laser irradiation data and droplet deposition data in accordance with shape information of a substrate that has been formed with a hole;
arranging a reflective surface of a light reflection device on a bottom of the hole to face toward an opening section of the hole;
directing a beam of laser light in accordance with the laser irradiation data to enter the hole through the opening section thereof to irradiate and modify an inner surface of the hole with the laser light reflected on the reflective surface; and
depositing droplets of conductive ink in accordance with the droplet deposition data into the hole of which the inner surface has been modified.

16. The pattern forming method as defined in claim 15, further comprising the steps of:
determining deviation of the substrate; and
correcting the laser irradiation data and the droplet deposition data in accordance with the determined deviation of the substrate.

17. The pattern forming method as defined in claim 15, further comprising the step of supplying reactive gas to the hole simultaneously with the directing of the beam of the laser light to enter the hole.

18. A method of manufacturing a substrate formed with patterns, the method comprising the steps of:
acquiring laser irradiation data and droplet deposition data in accordance with shape information of a substrate that has been formed with a hole;
arranging a reflective surface of a light reflection device on a bottom of the hole to face toward an opening section of the hole;
directing a beam of laser light in accordance with the laser irradiation data to enter the hole through the opening section thereof to irradiate and modify an inner surface of the hole with the laser light reflected on the reflective surface; and
depositing droplets of conductive ink in accordance with the droplet deposition data into the hole of which the inner surface has been modified.

19. The method as defined in claim 18, further comprising the steps of:
determining deviation of the substrate; and
correcting the laser irradiation data and the droplet deposition data in accordance with the determined deviation of the substrate.

20. The method as defined in claim 18, further comprising the step of supplying reactive gas to the hole simultaneously with the directing of the beam of the laser light to enter the hole.
